(19) United States
(12) Patent Application Publication
(10) Pub. No.: US 2009/0321854 A1
(43) Pub. Date: Dec. 31, 2009

(54) MIS FIELD EFFECT TRANSISTOR AND METHOD FOR MANUFACTURING THE SAME

(76) Inventors: Hiroaki Ohta, Kyoto (JP); Hidemi Takasu, Hyoto (JP); Hirotaka Otake, Kyoto (JP)

Correspondence Address: RABIN & Berdo, PC, 1101 14TH STREET, NW, SUITE 500, WASHINGTON, DC, 20005, US

(21) Appl. No.: 12/310,362

(22) PCT Filed: Aug. 22, 2007
(86) PCT No.: PCT/JP2007/066294

§ 371 Date: Feb. 23, 2009

(30) Foreign Application Priority Data
Aug. 24, 2006 (JP) 2006-228028
Mar. 6, 2007 (JP) 2007-056430

(51) Int. Cl. H01L 29/78

(52) U.S. Cl. 257/411; 257/288; 257/E29.255

(57) ABSTRACT

An MIS field effect transistor includes a nitride semiconductor multilayer structure including a first group III-V nitride semiconductor layer of a first conductivity type, a second group III-V nitride semiconductor layer of a second conductivity type which is arranged on the first group III-V nitride semiconductor layer, and a third group III-V nitride semiconductor layer of the first conductivity type which is arranged on the second group III-V nitride semiconductor layer. A gate insulating film is formed on a wall surface ranging over the first, second and third group III-V nitride semiconductor layers so that the film stretches over the first, second and third group III-V nitride semiconductor layer. A gate electrode made of a conductive material is formed so that it faces the second group III-V nitride semiconductor layer via the gate insulating film. A drain electrode is provided to be electrically connected to the first group III-V nitride semiconductor layer, and a source electrode is provided to be electrically connected to the third group III-V nitride semiconductor layer.

### TECHNICAL FIELD

The present invention relates to an MIS field-effect transistor employing group III-V nitride semiconductors and a method for manufacturing the same.

### PRIOR ART

In general, a power device employing a silicon semiconductor is employed for a power amplifier circuit, a power supply circuit, a motor driving circuit or the like.

However, improvement in breakdown voltage, reduction in resistance and improvement in speed of a silicon device are now reaching the limits due to the theoretical limit of the silicon semiconductor, and it is becoming difficult to satisfy requirements of the market.

Therefore, development of a GaN device having characteristics such as a high breakdown voltage, a high-temperature operation, a high current density, high-speed switching and small on-resistance is examined (see following Non-Patent Document 1).
Patent Document 1: Japanese Unexamined Patent Publication No. 2004-260140
Patent Document 2: Japanese Unexamined Patent Publication No. 2000-912523
Non-Patent Document 1: Satoshi Okubo, “Not Only Shining Any Longer GaN Behind Evolution of Devices”, Jun. 5, 2006, Nikkei Electronics, p. 51-60

### DISCLOSURE OF THE INVENTION

### Problems to be Solved by the Invention

However, every one of heretofore proposed GaN devices has a lateral structure obtained by arranging a source, a gate and a drain along a substrate surface, is not necessarily suitable for a power device requiring a high current, and insufficient in breakdown voltage either. Further, it is not necessarily easy to implement a normally-off operation which can be regarded as indispensable for a power device.

Accordingly, an object of the present invention is to provide a group III-V nitride semiconductor MIS field-effect transistor suitable for application to a power device and a method for manufacturing the same.

### Solutions to the Problems

An MIS field-effect transistor according to one aspect of the present invention includes: a nitride semiconductor multilayer structure portion (2) including a first group III-V nitride semiconductor layer (5, 55) of a first conductivity type, a second group III-V nitride semiconductor layer (6) of a second conductivity type stacked on the first group III-V nitride semiconductor layer and a third group III-V nitride semiconductor layer (7, 57) of the first conductivity type stacked on the second group III-V nitride semiconductor layer; a gate insulating film (19, 50) formed on a wall surface (17) formed over the first, second and third group III-V nitride semiconductor layers to extend over these first, second and third group III-V nitride semiconductor layers; a gate electrode (20) made of a conductive material formed as being opposed to the second group III-V nitride semiconductor layer (more preferably, a region extending over the first to third group III-V nitride semiconductor layers) with the gate insulating film interposed therebetween; a drain electrode (15) electrically connected to the first group III-V nitride semiconductor layer; and a source electrode (25) electrically connected to the third group III-V nitride semiconductor layer.

While the alphanumeric characters in the parentheses denote corresponding components etc. in embodiments described later, it is not intended that the scope of the present invention is to be interpreted limitedly to the embodiments. This also applies in this section.

According to this structure, the nitride semiconductor multilayer structure portion of an NPN structure or a PNP structure is formed by stacking the first group III-V nitride semiconductor layer, the second group III-V nitride semiconductor layer and the third group III-V nitride semiconductor layer, and the gate insulating film is arranged on the wall surface formed over the first to third group III-V nitride semiconductor layers. A portion of the second group III-V nitride semiconductor layer forming the wall surface forms a channel region, and the gate electrode is opposed to the channel region. Further, the drain electrode is provided to be electrically connected to the first group III-V nitride semiconductor layer, and the source electrode is provided to be electrically connected to the third group III-V nitride semiconductor layer. The drain electrode and the source electrode may simply be electrically connected to the first group III-V nitride semiconductor layer and the third group III-V nitride semiconductor layer respectively, and not less than two semiconductor layers different in composition and impurity from each other may be stacked between these electrodes and the semiconductor layers. Thus, a vertical MIS (Metal Insulator Semiconductor) field-effect transistor is comprised.

Thus, a normally-off operation, i.e., an operation for setting an OFF-state between the source and the drain when applying no bias to the gate electrode can be easily implemented due to the basic structure as the vertical MIS field-effect transistor. Further, a high current can be easily fed due to the vertical structure, while a high breakdown voltage can be so ensured that an effective power device can be provided. Needless to say, the field-effect transistor is constituted of the group III-V nitride semiconductor layers, whereby the same can attain characteristics such as a high breakdown voltage, a high-temperature operation, a high current density, high-speed switching and small on-resistance as compared with a device employing a silicon semiconductor. In particular, the MIS field-effect transistor is capable of an operation with a high breakdown voltage and low loss, whereby an excellent power device can be implemented.

The group III-V nitride semiconductors are semiconductors employing nitrogen as a group V element in group III-V semiconductors, and aluminum nitride (AlN), gallium nitride (GaN) and indium nitride (InN) are typical examples. The same can be generally expressed as AlₓIn_{y}Ga_{1-x-y}N (0≦x≦1, 0≦y≦1 and 0≦x+y≦1).

An operation in a case of constituting an N-channel MIS field-effect transistor by setting the first group III-V nitride semiconductor layer and the third group III-V nitride semiconductor layer to N-types and setting the second group III-V nitride semiconductor layer to a P-type, for example, is described. In this case, a bias positive on the drain side is supplied between the source and the drain. At this time, it follows that a reverse voltage is applied to the P-N junction portion on the interface between the first and second group III-V nitride semiconductor layers, and hence the source and the drain are cut off. When applying a bias voltage positive with respect to the second group III-V nitride semiconductor layer to the gate electrode from this state, electrons are induced in a region (channel region) around the wall surface opposed to the gate electrode in the second group III-V nitride semiconductor layer, and an inversion channel is formed. The first and third group III-V nitride semiconductor layers conduct through this inversion channel, and hence it follows that the source and the drain conduct. Thus, the source and the drain conduct when supplying a proper bias to the gate electrode, while the source and the drain are cut off when supplying no bias to the gate electrode. In other words, the normally-off operation is implemented. In a case of constituting a P-channel field-effect transistor by setting the first and third group III-V nitride semiconductor layers to P-types and setting the second group III-V nitride semiconductor layer to an N-type, the operation is similar to the above while the polarity of the bias voltage is reversed.

A trench (16) reaching the first group III-V nitride semiconductor layer may be formed from the third group III-V nitride semiconductor layer through the second group III-V nitride semiconductor layer, and the sidewall of this trench may form the wall surface. According to this structure, the MIS structure can be constituted up to a depletion layer spreading in the first and third group III-V nitride semiconductor layers above and under the second group III-V nitride semiconductor layer. When a channel is formed in the second group III-V nitride semiconductor layer, therefore, a storage layer is formed also in the depletion layer spreading in the first and third group III-V nitride semiconductor layers, and a current can be fed without being inhibited from this depletion layer in an ON-state. Consequently, on-resistance can be further reduced.

For example, a depletion layer spreading in an n-type layer by an internal potential in an n-p-n vertical structure is expressed in the following numerical formula in one-sided abrupt junction:

W=\sqrt{2εₛV_{bi}/qN_{D}} [Numerical Formula 1]

(W: depletion layer width, εₛ: dielectric constant of group III-V nitride semiconductor, V_{bi}: internal potential of p-n junction, q: elementary electric charge, N_{D}: impurity concentration in n-type layer)

Assuming that, in the above formula, the group III-V nitride semiconductor is gallium nitride (GaN),

the impurity concentration in an n-type first layer (first group III-V nitride semiconductor layer) is N_{D}=5×10¹⁶ cm⁻³,

the impurity concentration in a p-type second layer (second group III-V nitride semiconductor layer) is 1×10¹⁸ cm⁻³, and

the impurity concentration in an n-type third layer (third group III-V nitride semiconductor layer) is 3×10¹⁸ cm⁻³, the width of a depletion layer spreading in the n-type first layer is W=0./25 (μm), assuming that the elementary electric charge q=1.6×10⁻¹⁹ (C), the dielectric constant εₛ=9.5×8.85×10⁻¹⁴ (F/cm), and the internal potential V_{bi}=3 (V).

When forming the wall surface in the range of not less than 0.25 μm at least from the p-n junction between the p-type second layer and the n-type first layer and forming an MIS structure in this range, a current can be fed without being inhibited by the depletion layer in an ON-state.

The trench may be a sectionally V-shaped trench, may be a sectionally U-shaped trench, or may be a sectionally rectangular trench. The trench may be a V-shaped trench (inverted trapezoidal groove) having a planar surface on the bottom portion, or may be a trench having a trapezoidal sectional shape.

The first group III-V nitride semiconductor layer may include a lower layer and an upper layer, having a smaller impurity concentration than the lower layer, held between this lower layer and the second group III-V nitride semiconductor layer. According to this structure, the depletion layer can be spread toward the upper layer side of the first group III-V nitride semiconductor layer when the transistor operates in a saturation region. Therefore, spreading of the depletion layer toward the second group III-V nitride semiconductor layer side can be reduced, and reach-through breakdown can be suppressed.

A second trench different from the trench may be formed to reach at least the first group III-V nitride semiconductor layer, and the drain electrode may be formed on the bottom surface of this second trench.

According to this structure, the second trench on which the drain electrode is formed is formed separately from the trench on which the gate electrode is formed. Therefore, the second trench for forming the drain electrode and the trench for forming the gate can be controlled to a deep shape and a shallow shape respectively. The surface area of the first group III-V nitride semiconductor layer opposed to the gate electrode can be reduced due to this control, whereby interfacial charge on this first group III-V nitride semiconductor layer can be reduced. Consequently, an off-leakage current can be reduced, and the on-resistance can be reduced. Further, the source, the gate and the drain are not arranged on the same surface in this order, but off characteristics can be improved.

The source electrode may be provided to be in contact with both of the second group III-V nitride semiconductor layer and the third group III-V nitride semiconductor layer.

According to this structure, the source electrode is in contact with both of the second and third group III-V nitride semiconductor layers, whereby the second group III-V nitride semiconductor layer can be fixed to the same potential as the source at the same time when connection of the source electrode to the third group III-V nitride semiconductor layer is ensured. Therefore, an inversion channel can be formed on a portion (channel region) of the second group III-V nitride semiconductor layer opposed to the wall surface by supplying a bias to the gate electrode with respect to the source potential.

For example, a trench (24) for embedding the source electrode maybe formed on a position of the nitride semiconductor multilayer structure portion different from the wall surface, so that the source electrode is embedded in this trench. In this case, the trench for the source electrode may be formed in a depth reaching the second group III-V nitride semiconductor layer from the third group III-V nitride semiconductor layer.

The nitride semiconductor multilayer structure portion may further include a fourth group III-V nitride semiconductor layer (9) of the first conductivity type arranged on a side opposite to the second group III-V nitride semiconductor layer with respect to the first group III-V nitride semiconductor layer (may be arranged in contact with the first group III-V nitride semiconductor layer). In this case, the drain electrode may be connected to the fourth group III-V nitride semiconductor layer.

According to this structure, the drain electrode is connected to the fourth group III-V nitride semiconductor layer formed in contact with the first group III-V nitride semiconductor layer, whereby the drain electrode can be electrically connected to the first group III-V nitride semiconductor layer through the fourth group III-V nitride semiconductor layer. Even when the nitride semiconductor multilayer structure portion is provided on an insulating substrate, the electrical connection between the drain electrode and the first group III-V nitride semiconductor layer can be attained through the fourth group III-V nitride semiconductor layer. The impurity concentration in the fourth group III-V nitride semiconductor layer is preferably high, and preferably 10¹⁸ cm⁻³, for example. Thus, the on-resistance can be reduced. Between the first group III-V nitride semiconductor layer and the fourth group III-V nitride semiconductor layer, a semiconductor layer different from these may be interposed.

The nitride semiconductor multilayer structure portion may further include a fourth group III-V nitride semiconductor layer (9) of the first conductivity type containing Al arranged on a side opposite to the second group III-V nitride semiconductor layer with respect to the first group III-V nitride semiconductor layer (may be arranged in contact with the first group III-V nitride semiconductor layer).

According to this structure, the fourth group III-V nitride semiconductor layer of the same conductivity type as the first group III-V nitride semiconductor layer is provided to be in a stacking relation with the first group III-V nitride semiconductor layer. The fourth group III-V nitride semiconductor layer contributes to improvement of the breakdown voltage and reduction of the resistance. When forming the first group III-V nitride semiconductor layer and the fourth group III-V nitride layer by a GaN layer and an AlGaN layer respectively, for example, lateral conductivity can be improved by electron gas generated on the AlGaN/GaN interface.

In this case, the drain electrode may be connected to (in contact with) the fourth group III-V nitride semiconductor layer. According to this structure, the drain electrode can be electrically connected to the first group III-V nitride semiconductor layer through the fourth group III-V nitride semiconductor layer. When the nitride semiconductor multilayer structure portion is arranged on a substrate, connection of the drain electrode can be performed through the fourth group III-V nitride semiconductor layer even when the substrate is an insulating substrate.

The fourth group III-V nitride semiconductor layer may be a layer formed by stacking a plurality of layers having different Al compositions. According to this structure, two-dimensional electron gas can be utilized similarly to a case described later by setting the Al compositions of the plurality of layers (AlGaN superlattice layers, for example) constituting the fourth group III-V nitride semiconductor layer to proper compositions. Thus, resistivity in the fourth group III-V nitride semiconductor layer can be reduced, whereby the on-resistance of the transistor can be reduced.

The nitride semiconductor multilayer structure portion may further include a fifth group III-V nitride semiconductor layer (8) which is an intrinsic semiconductor layer (undoped) arranged on a side opposite to the first group III-V nitride semiconductor layer with respect to the fourth group III-V nitride semiconductor layer (preferably arranged in contact with the fourth group III-V nitride semiconductor layer).

In this structure, the fourth group III-V nitride semiconductor layer and the fifth group III-V nitride semiconductor layer consisting of the intrinsic semiconductor layer are arranged in a stacking relation. Around the boundary between these fourth and fifth group III-V nitride semiconductor layers, two-dimensional electron gas (28) of a high concentration is formed in the fifth group III-V nitride semiconductor layer. The resistance value of a portion reaching the drain electrode from the first group III-V nitride semiconductor layer can be reduced by utilizing this two-dimensional electron gas, and further reduction in resistance can be attained. Particularly, also in a case of drawing the drain in the lateral direction of the nitride semiconductor multilayer structure portion through the fourth group III-V nitride semiconductor layer, for example, a current flowing between the same and the two-dimensional electron gas can be dispersed in a wide range of the first group III-V nitride semiconductor layer. Thus, concentration of the current can be suppressed, and reduction in resistance of the device is implemented.

In this case, the fifth group III-V nitride semiconductor layer is preferably a layer doped with Mg, C or Fe. The nitride semiconductor tends to be slightly N-typed in formation (epitaxy) thereof, and hence the fifth group III-V nitride semiconductor layer can be formed by the intrinsic semiconductor layer by doping the same with Mg, C or Fe as the P-type dopant in order to cancel this.

The third group III-V nitride semiconductor layer may be a layer formed by stacking a plurality of layers having different compositions. When a GaN layer is stacked on a side closer to the substrate and an Al_{0.2}Ga_{0.8}N layer is stacked on this GaN layer in the third group III-V nitride semiconductor layer, for example, two-dimensional electron gas having a sheet carrier density of 1×10¹³ cm⁻³ and electron mobility of 1000 cm²/V·s is formed around the boundary between these two layers according to this structure, whereby resistance parasitic on the third group III-V nitride semiconductor layer can be reduced, and the on-resistance of the transistor can be reduced. The plurality of layers having different compositions may be AlGaN superlattice layers, or may be a plurality of AlGaN layers having different compositions.

The first group III-V nitride semiconductor layer may be a layer formed by stacking a plurality of layers having different compositions. When a GaN layer is stacked on a side closer to the substrate and an Al_{0.2}Ga_{0.8}N layer is stacked on this GaN layer in the first group III-V nitride semiconductor layer, for example, two-dimensional electron gas having a sheet carrier density of 1×10¹³ cm⁻³ and electron mobility of 1000 cm²/V·s is formed around the boundary between these two layers according to this structure, whereby resistance parasitic on the first group III-V nitride semiconductor layer can be reduced, and the on-resistance of the transistor can be reduced. The plurality of layers having different compositions may be AlGaN superlattice layers, or maybe a plurality of AlGaN layers having different compositions.

The nitride semiconductor multilayer structure portion may be formed (grown) on a substrate (1, 41). The substrate may be an insulating substrate (1). A typical insulating substrate is a sapphire (Al₂O₃) substrate. Also in a case of employing such an insulating substrate, the aforementioned structure can be employed, or the transistor can be brought into a structure directly bringing the drain electrode into contact with the first group III-V nitride semiconductor layer. Thus, the drain electrode can be electrically connected to the first group III-V nitride semiconductor layer.

The substrate may be an Al₂O₃ substrate, a ZnO substrate, an Si substrate, a GaAs substrate, a GaN substrate or an SiC substrate. The GaN substrate is the best in view of the matching property of the lattice constant with the nitride semiconductor structure portion, and nitride semiconductor layers having small numbers of dislocations can be formed by employing the GaN substrate. The Al₂O₃ substrate (sapphire substrate) is preferably employed in view of reduction in cost, while the SiC substrate may be employed when attaching importance to heat radiation (heat conductivity)

The substrate may be a substrate having a region exhibiting a high dislocation density and a region exhibiting a small dislocation density in a direction along the substrate surface. In this case, the gate electrode is preferably arranged to be opposed to a region grown from the region exhibiting a low dislocation density.

In a substrate having an epitaxial growth layer formed by epitaxial lateral overgrowth (ELO) as described in Patent Document 2, for example, a region (dislocation-free region) exhibiting a low dislocation density and a region exhibiting a high dislocation density are present in the epitaxial growth layer. When the channel region (region opposed to the wall surface) of the second group III-V nitride semiconductor layer is positioned on a region grown from the region exhibiting a low dislocation density in this case, the dislocation density of the channel region so lowers that a leakage current can be suppressed.

The nitride semiconductor multilayer structure portion may be arranged on one surface of a conductive substrate (41), and the drain electrode may be connected to (in contact with) the other surface of the conductive substrate.

According to this structure, the nitride semiconductor multilayer structure portion is arranged on one surface of the conductive substrate, and the drain electrode is so connected to the other surface of the conductive substrate that this drain electrode is electrically connected to the first group III-V nitride semiconductor layer. Thus, the current flows through a wide range of the nitride semiconductor multilayer structure portion, whereby current narrowing can be suppressed, while a high breakdown voltage can be attained at the same time.

A ZnO substrate, an Si substrate, a GaAs substrate, a GaN substrate or an SiC substrate can be applied as the conductive substrate. In particular, the lattice constant of the GaN substrate matches with that of the nitride semiconductor multilayer structure portion, whereby crystallinity of the nitride semiconductor multilayer structure portion can be improved by employing the GaN substrate.

The drain electrode may be connected to (in contact with) the first group III-V nitride semiconductor layer. According to this structure, the drain electrode can be electrically connected to the first group III-V nitride semiconductor layer.

The drain electrode may be formed in contact with a surface of the nitride semiconductor multilayer structure portion opposite to the gate electrode.

According to this structure, the drain electrode is formed in contact with the surface of the nitride semiconductor multilayer structure portion opposite to the gate electrode, and hence the substrate can be omitted. More specifically, the drain electrode may formed in contact with a surface of the first group III-V nitride semiconductor layer opposite to the second first group III-V nitride semiconductor layer.

According to this structure, an MIS field-effect transistor having a thickness or not more than 30 μm can be implemented, for example.

Preferably, the first group III-V nitride semiconductor layer has a larger band gap than the second group III-V nitride semiconductor layer. According to this structure, the breakdown voltage can be further improved due to the large band gap of the first group III-V nitride semiconductor layer.

More specifically, the first group III-V nitride semiconductor layer preferably contains Al. Further, the first group III-V nitride semiconductor layer preferably contains not less than 5 weight % of Al.

Preferably, the third group III-V nitride semiconductor layer has a larger band gap than the second group III-V nitride semiconductor layer. According to this structure, the band gap of the third group III-V nitride semiconductor layer is enlarged, whereby improvement of the breakdown voltage can be attained. In particular, improvement of the breakdown voltage can be more effectively attained by forming a double heterojunction by rendering the band gaps of both of the first and third group III-V nitride semiconductor layers larger than the band gap of the second group III-V nitride semiconductor layer.

Preferably, the third group III-V nitride semiconductor layer contains Al. Further, the third group III-V nitride semiconductor layer preferably contains not less than 5 weight % of Al.

The first, second and third group III-V nitride semiconductor layers maybe stacked with major surfaces defined by C-planes (0001).

The first, second and third group III-V nitride semiconductor layers may be stacked with major surfaces defined by nonpolar planes (m-planes (10-10) or a-planes (11-20)) or semipolar planes ((10-1-1), (10-1-3), (11-22) or the like).

Preferably, the wall surface of the first, second and third group III-V nitride semiconductor layers on which the gate insulating film is formed is defined by a nonpolar plane (an m-plane (10-10) or an a-plane (11-20)) or a semipolar plane ((10-1-1), (10-1-3), (11-22) or the like). The wall surface is not restricted to the nonpolar plane or the semipolar plane, but may have an angle close thereto. The nonpolar plane or the semipolar plane has high crystal symmetry and is extremely stable, whereby an excellent interface can be obtained, and interfacial charge can be reduced.

The gate insulating film may be a nitride, an oxide or an oxynitride. In particular, the gate insulating film is preferably made of silicon nitride, silicon oxide or silicon oxynitride.

The gate insulating film may include a group III-V nitride intrinsic semiconductor gate layer (51: regrowth layer) containing Al.

According to this structure, the gate insulating film is brought into the structure having the group III-V nitride intrinsic semiconductor gate layer (preferably containing no In) containing Al. This group III-V nitride intrinsic semiconductor gate layer forms an excellent interface between the same and the wall surface of the first to third group III-V nitride semiconductor layers. Therefore, such inconveniences that the carrier mobility in the channel region lowers and the reliability of the device lowers due to an unstable interface can be avoided dissimilarly to a case of forming an insulating film such as an oxide film in contact with the wall surface of the first to third group III-V nitride semiconductor layers.

The gate insulating film may include another insulating film (52) stacked on the group III-V nitride intrinsic semiconductor gate layer containing Al. In this case, the other insulating film is preferably stacked on the group III-V nitride intrinsic semiconductor gate layer on a side opposite to the wall surface.

According to this structure, a gate leakage current can be reduced. The group III-V nitride intrinsic semiconductor gate layer containing Al may be insufficient in insulating property if the Al composition is small. In this case, the insufficient insulating property of the group III-V nitride intrinsic semiconductor gate layer containing Al is preferably compensated with the other insulating film.

Preferably, the Al composition in the group III-V nitride intrinsic semiconductor gate layer containing Al is 50 to 100 weight % (not less than 50 weight % and less than 100 weight %). Thus, a necessary insulating property can be ensured.

Preferably, the conductive material constituting the gate electrode consists of a simple metal or an alloy containing at least any one of Al, Au and Pt. The conductive material constituting the gate electrode may contain polysilicon.

On the other hand, the source electrode or the drain electrode is preferably made of a material containing at least Al. More specifically, the source electrode or the drain electrode is preferably made of an alloy material containing at least Ti and Al. Thus, contact for wiring can be excellently attained with respect to the source electrode or the drain electrode. The material constituting the source electrode or the drain electrode may contain Mo or an Mo compound, Ti or a Ti compound, or W or a W compound.

An MIS field-effect transistor according to another aspect of the present invention includes: a nitride semiconductor multilayer structure portion including a first group III-V nitride semiconductor layer of a first conductivity type, a second group III-V nitride semiconductor layer of a second conductivity type stacked on this first group III-V nitride semiconductor layer and a third group III-V nitride semiconductor layer of the first conductivity type stacked on this second group III-V nitride semiconductor layer; a gate insulating film formed on a wall surface formed over the first, second and third group III-V nitride semiconductor layers to extend over these first, second and third group III-V nitride semiconductor layers; a gate electrode made of a conductive material formed as being opposed to the second group III-V nitride semiconductor layer with the gate insulating film interposed therebetween; a drain electrode electrically connected to the first group III-V nitride semiconductor layer; and a source electrode electrically connected to the third group III-V nitride semiconductor layer, wherein the gate insulating film contains a nitride and an oxide, and an insulating film in contact with the wall surface is a nitride. More specifically, the nitride may be silicon nitride, for example, and the oxide may be silicon oxide, for example.

According to this structure, interfacial charge on the wall surface can be suppressed and an off-leakage current can be reduced by preparing the insulating film in contact with the wall surface from a nitride. While the breakdown voltage is low when constituting the gate insulating film only of the nitride (silicon nitride), the breakdown voltage can be improved by bringing the gate insulating film into the structure containing the nitride and the oxide. Consequently, a transistor operation can be improved. An oxynitride (silicon oxynitride, for example) may also be employed, if necessary.

Preferably, the aforementioned gate insulating film is formed by ECR (electron cyclotron resonance) sputtering. A more excellent transistor operation can be performed when the gate insulating film is a silicon nitride film formed by ECR sputtering.

Preferably, the gate insulating film is an insulating film continuously formed while a wafer on which the MIS field-effect transistor is formed is not taken out from a film forming apparatus.

A method for manufacturing an MIS field-effect transistor according to the present invention includes: a step of forming a first group III-V nitride semiconductor layer (5, 55) of a first conductivity type on a substrate (1, 41, 45); a step of stacking and forming a second group III-V nitride semiconductor layer (6) of a second conductivity type on the first group III-V nitride semiconductor layer; a step of stacking and forming a third group III-V nitride semiconductor layer (7, 57) of the first conductivity type on the second group III-V nitride semiconductor layer; a wall surface forming step of forming a wall surface (17) extending over the first, second and third group III-V nitride semiconductor layers; a gate insulating film forming step of forming a gate insulating film (19, 50) on the wall surface to extend over the first, second and third group III-V nitride semiconductor layers; a step of forming a gate electrode (29) made of a conductive material to be opposed to the second group III-V nitride semiconductor layer with the gate insulating film interposed therebetween; a step of forming a drain electrode (15) to be electrically connected to the first group III-V nitride semiconductor layer; and a step of forming a source electrode (25) to be electrically connected to the third group III-V nitride semiconductor layer. According to this method, the MIS field-effect transistor having the aforementioned structure can be manufactured.

The wall surface forming step may include a trench forming step of forming a trench (16) reaching the first group III-V nitride semiconductor layer from the third group III-V nitride semiconductor layer through the second group III-V nitride semiconductor layer, and the sidewall of this trench may form the wall surface.

Preferably, the trench forming step includes a dry etching step and a wet etching step of removing a damaged layer resulting from this dry etching step.

According to this method, the damaged layer resulting from the dry etching step is removed by the wet etching step. Consequently, damage on the wall surface on which the gate insulating film is formed, i.e., the surface of a channel region can be reduced, whereby interfacial charge between the wall surface of the second group III-V nitride semiconductor layer and the gate insulating film can be reduced. Thus, mobility in the channel region can be improved.

The wet etching step may include a wet etching step employing an alkaline solution as an etching solution. As the alkaline solution, KOH (potassium hydroxide) or NH₄OH (ammonia water) can be employed.

The step of forming the gate insulating film may include a step of growing a group III-V nitride intrinsic semiconductor layer (51) containing Al on the wall surface.

The step of forming the gate insulating film may include a step of stacking another insulating film (52) on the group III-V nitride intrinsic semiconductor layer containing Al.

The method may further include a step of removing the substrate (45). In this case, the step of forming the drain electrode may include a step of forming the drain electrode on the surface of a group III-V nitride semiconductor layer exposed by the removal of the substrate.

It follows that the substrate is finally removed, and hence the same may be either conductive or insulative. In other words, a vertical MIS field-effect transistor can be prepared without employing a conductive substrate. More specifically, a vertical MIS field-effect transistor can be prepared by employing a low-priced sapphire substrate, for example.

The foregoing and other objects, features and effects of the present invention will become more apparent from the following detailed description of the embodiments with reference to the attached drawings.

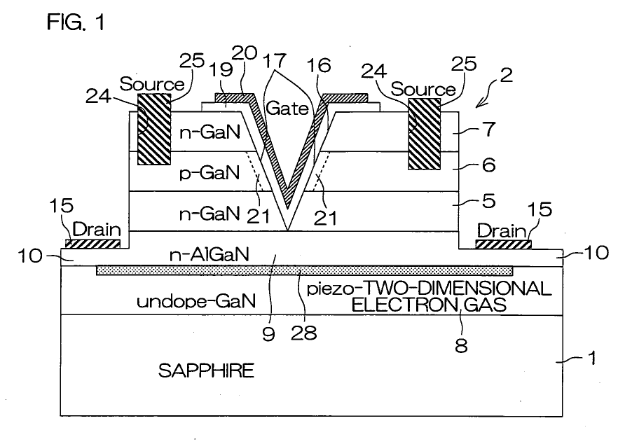

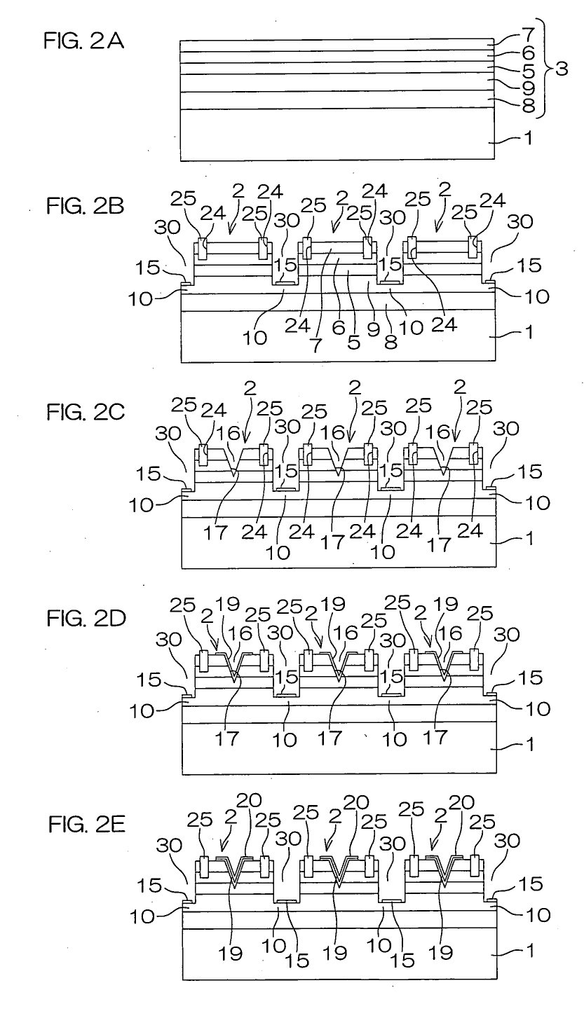

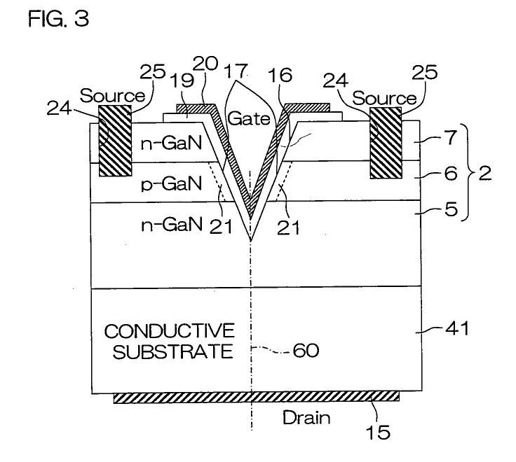

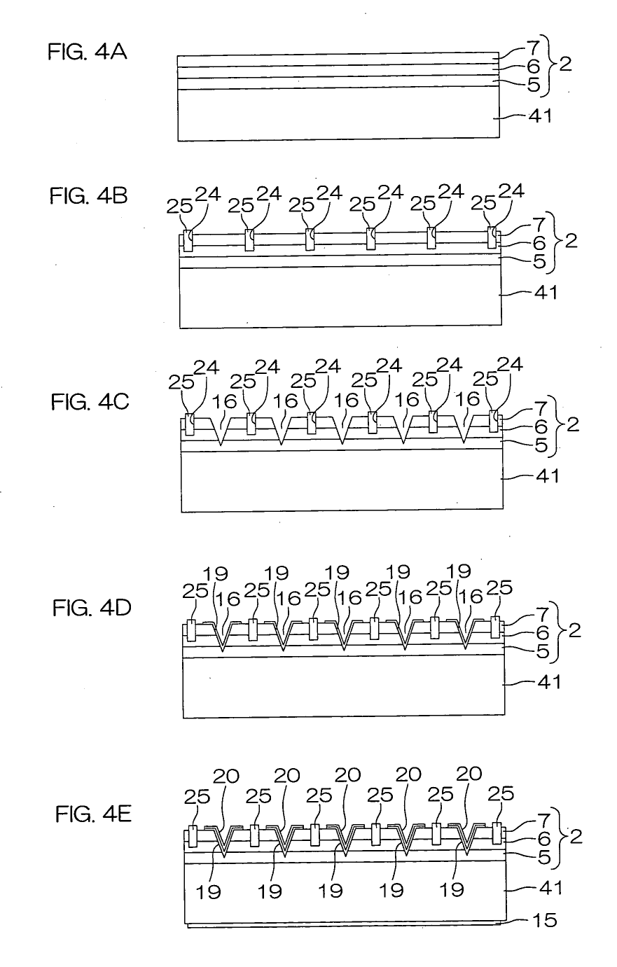

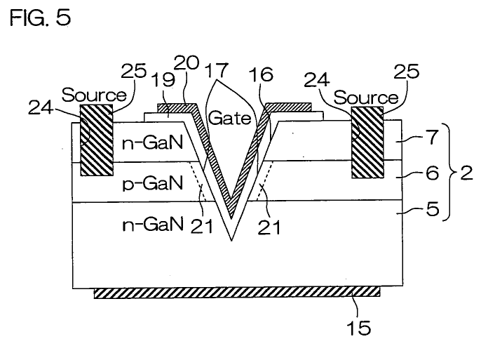

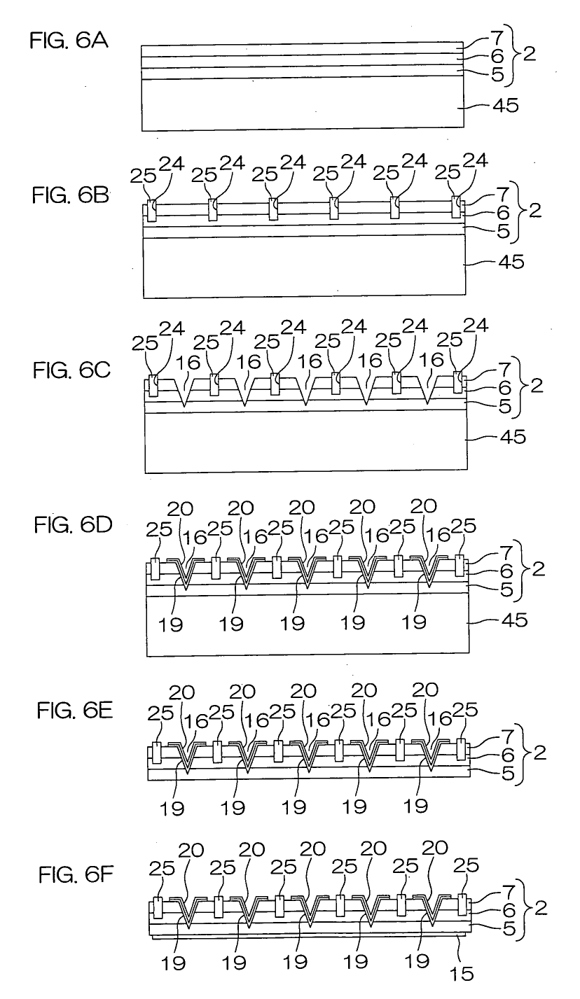

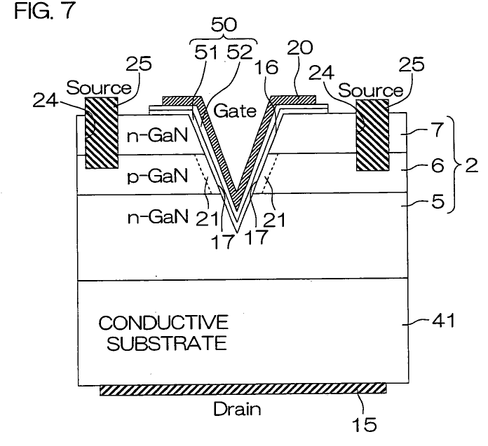

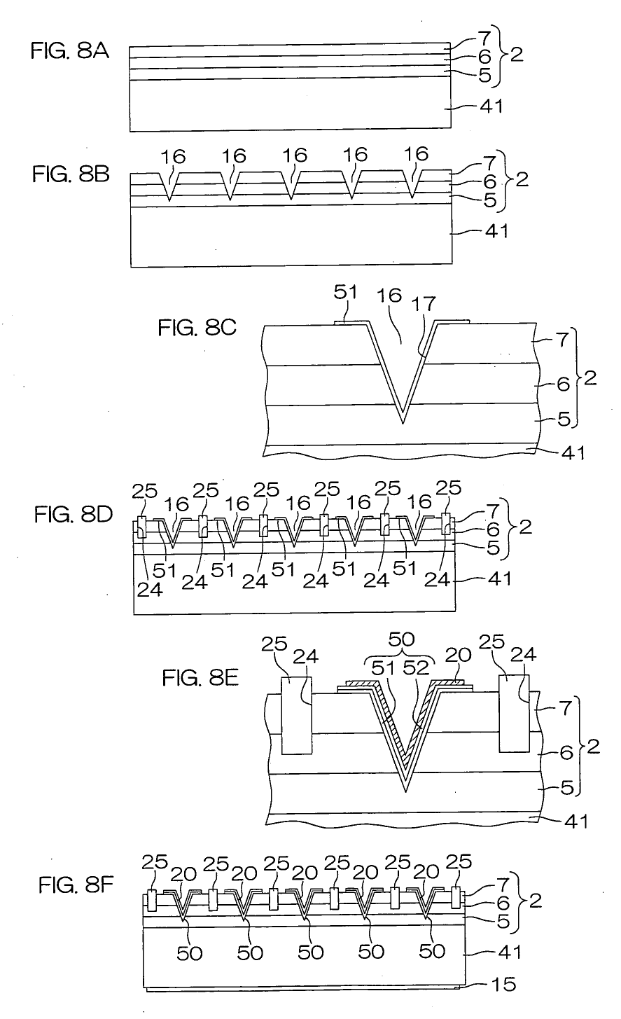

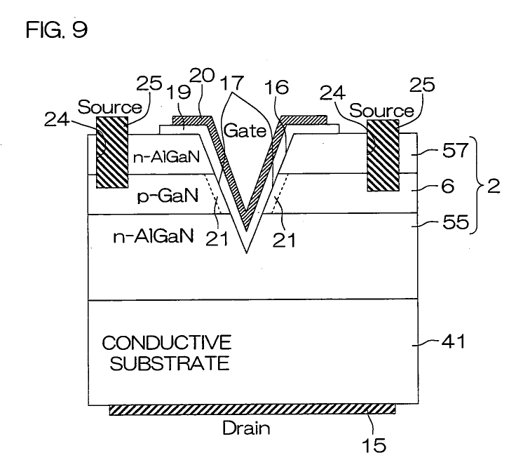

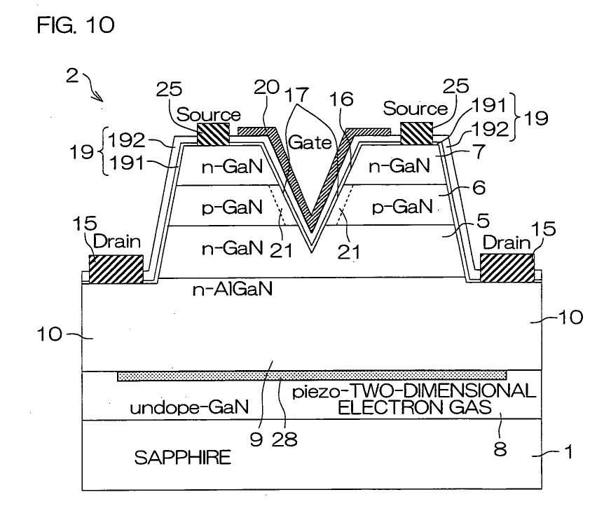

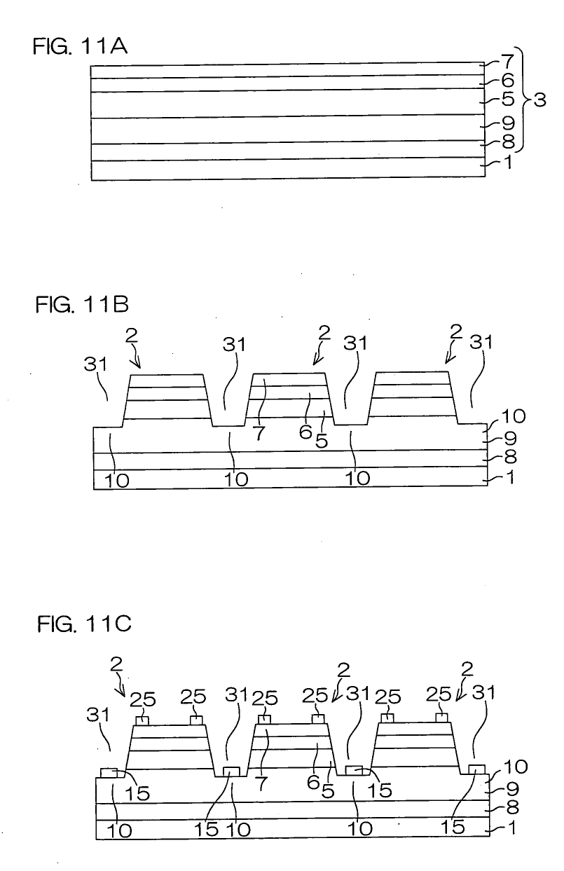

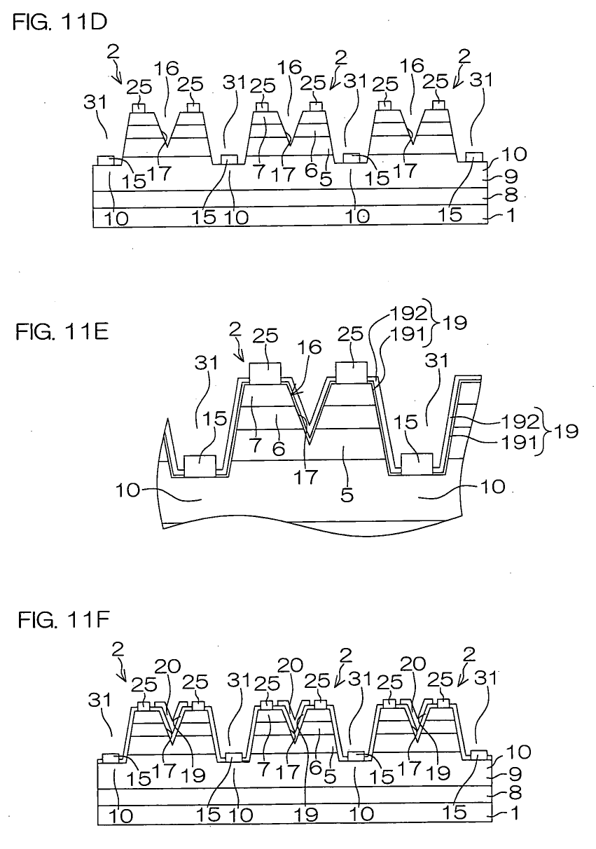

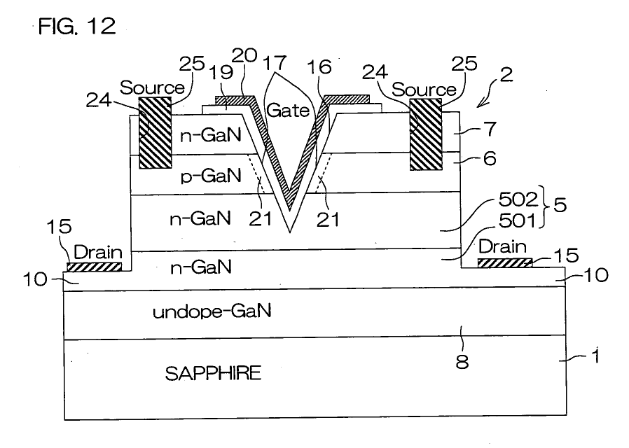

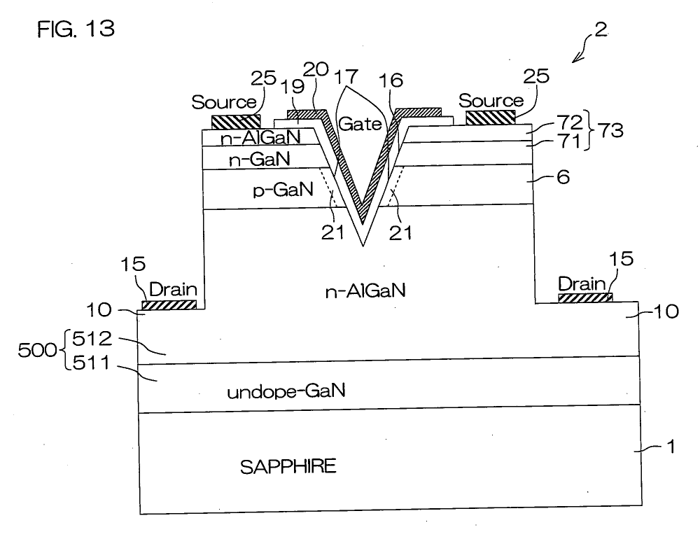

### BRIEF DESCRIPTION OF THE DRAWINGS

[FIG. 1] A schematic sectional view for illustrating the structure of an MIS field-effect transistor according to a first embodiment of the present invention.

[FIG. 2] FIGS. 2A to 2E are schematic sectional views showing a method for manufacturing the MIS field-effect transistor of FIG. 1 in step order.

[FIG. 3] A schematic sectional view for illustrating the structure of an MIS field-effect transistor according to a second embodiment of the present invention.

[FIG. 4] FIGS. 4A to 4E are schematic sectional views showing a method for manufacturing the MIS field-effect transistor of FIG. 3 in step order.

[FIG. 5] A schematic sectional view for illustrating the structure of an MIS field-effect transistor according to a third embodiment of the present invention.

[FIG. 6] FIGS. 6A to 6F are schematic sectional views showing a method for manufacturing the MIS field-effect transistor of FIG. 5 in step order.

[FIG. 7] A schematic sectional view for illustrating the structure of an MIS field-effect transistor according to a fourth embodiment of the present invention.

[FIG. 8] FIGS. 8A to 8F are schematic sectional views showing a method for manufacturing the MIS field-effect transistor of FIG. 7 in step order.

[FIG. 9] A schematic sectional view for illustrating the structure of an MIS field-effect transistor according to a fifth embodiment of the present invention.

[FIG. 10] A schematic sectional view for illustrating the structure of an MIS field-effect transistor according to a sixth embodiment of the present invention.

[FIG. 11A] A schematic sectional view for illustrating a method for manufacturing the MIS field-effect transistor of FIG. 10.

[FIG. 11B] A schematic sectional view for illustrating the method for manufacturing the MIS field-effect transistor of FIG. 10, showing a step subsequent to FIG. 11A.

[FIG. 11C] A schematic sectional view for illustrating the method for manufacturing the MIS field-effect transistor of FIG. 10, showing a step subsequent to FIG. 11B.

[FIG. 11D] A schematic sectional view for illustrating the method for manufacturing the MIS field-effect transistor of FIG. 10, showing a step subsequent to FIG. 11C.

[FIG. 11E] A schematic sectional view for illustrating the method for manufacturing the MIS field-effect transistor of FIG. 10, showing a step subsequent to FIG. 11D.

[FIG. 11F] A schematic sectional view for illustrating the method for manufacturing the MIS field-effect transistor of FIG. 10, showing a step subsequent to FIG. lE.

[FIG. 12] A schematic sectional view for illustrating the structure of an MIS field-effect transistor according to a seventh embodiment of the present invention.

[FIG. 13] A schematic sectional view for illustrating the structure of an MIS field-effect transistor according to an eighth embodiment of the present invention.

### DESCRIPTION OF THE REFERENCE NUMERALS

1 . . . sapphire substrate, 2 . . . nitride semiconductor multilayer structure portion, 5 . . . N-type GaN layer, 6 . . . P-type GaN layer, 7 . . . N-type GaN layer, 8 . . . intrinsic GaN layer, 9 . . . N-type AlGaN layer, 10 . . . drawn portion, 15 . . . drain electrode, 16 . . . trench, 17 . . . wall surface, 19 . . . gate insulating film, 20 . . . gate electrode, 21 . . . channel region, 24 . . . source electrode trench, 25 . . . source electrode, 28 . . . two-dimensional electron gas, 30 . . . groove, 41 . . . conductive substrate, 45 . . . substrate, 50 . . . gate insulating film, 51 . . . AlGaN regrowth layer, 52 . . . insulating film, 55 . . . N-type AlGaN layer, 57 . . . N-type AlGaN layer, 71 . . . N-type GaN layer, 72 . . . N-type AlGaN layer, 73 . . . N-type nitride semiconductor layer, 191 . . . silicon nitride film, 192 . . . silicon oxide film, 500 . . . N-type nitride semiconductor layer, 501 . . . N-type GaN layer, 502 . . . N-type GaN layer, 511 . . . intrinsic GaN layer, 512 . . . N-type AlGaN layer

### BEST MODE FOR CARRYING OUT THE INVENTION

FIG. 1 is a schematic sectional view for illustrating the structure of an MIS field-effect transistor according to a first embodiment of the present invention. This field-effect transistor includes a sapphire substrate 1 which is an insulating substrate and a nitride semiconductor multilayer structure portion 2 consisting of GaN compound semiconductor layers grown on the sapphire substrate 1. The nitride semiconductor multilayer structure portion 2 includes an N-type GaN layer 5 (drain layer), a P-type GaN layer 6 stacked on the N-type GaN layer 5 and an N-type GaN layer 7 (source layer) stacked on the P-type GaN layer 6. Further, the nitride semiconductor multilayer structure portion 2 includes an intrinsic (undoped) GaN layer 8 formed in contact with the sapphire substrate 1 and an N-type AlGaN layer 9 stacked on this intrinsic GaN layer 8, and the N-type GaN layer 5 is stacked on this N-type AlGaN layer 9.

The nitride semiconductor multilayer structure portion 2 is etched up to such a depth that the N-type AlGaN layer 9 is exposed from the N-type GaN layer 7 so that the section is generally rectangular. The N-type AlGaN layer 9 has drawn portions 10 drawn from both sides of the nitride semiconductor multilayer structure portion 2 in a lateral direction along the surface of the sapphire substrate 1. Drain electrodes 15 are formed in contact with the surfaces of these drawn portions 10. In other words, the drawn portions 10 laterally drawn from the nitride semiconductor multilayer structure portion 2 are constituted of extensions of the N-type AlGaN layer 9 in this embodiment.

On the other hand, a trench 16 having a depth reaching an intermediate portion of the N-type GaN layer 5 from the N-type GaN layer 7 through the P-type GaN layer 6 is formed in the vicinity of a width-directional intermediate portion of the nitride semiconductor multilayer structure portion 2. According to this embodiment, the trench 16 is formed in a sectionally V-shaped manner, and inclined side surfaces thereof form wall surfaces 17 extending over the N-type GaN layer 5, the P-type GaN layer 6 and the N-type GaN layer 7. A gate insulating film 19 is formed on a region covering the overall regions of these wall surfaces 17 and reaching edge portions of the trench 16 on the upper surface of the N-type GaN layer 7. Further, a gate electrode 20 is formed on the gate insulating film 19. In other words, the gate electrode 20 is opposed to the wall surfaces 17, i.e., the N-type GaN layer 5, the P-type GaN layer 6 and the N-type GaN layer 7 with the gate insulating film 19 interposed therebetween, and further formed to extend up to portions around the edge portions of the trench 16 on the upper surface of the N-type GaN layer 7. In addition, the trench 16 on which the gate insulating film 19 and the gate electrode 20 are formed is provided on the position different from the drawn portions 10 on which the drain electrodes 15 are formed, whereby the depth of the trench 16 can be properly controlled regardless of the positions of arrangement of the drain electrodes 15. The surface area of the N-type GaN layer 5 opposed to the gate electrode 20 can be reduced due to this control, whereby interfacial charge on the N-type GaN layer 5 can be reduced. Consequently, an off-leakage current can be reduced, and on-resistance can be reduced.

Regions around the wall surfaces 17 in the P-type GaN layer 6 are channel regions 21 opposed to the gate electrode 20. A proper bias voltage is so applied to the gate electrode 20 that inversion channels electrically conducting the N-type GaN layers 5 and 7 are formed in these channel regions 21.

In the nitride semiconductor multilayer structure portion 2, source electrode trenches 24 are formed on positions different from the trench 16. According to this embodiment, a pair of source electrode trenches 24 are formed on both sides of the trench 16. The source electrode trenches 24 are formed up to a depth reaching the P-type GaN layer 6 from the surface of the N-type GaN layer 7. Source electrodes 25 are embedded in these source electrode trenches 24. Therefore, it follows that the source electrodes 25 are electrically connected to both of the N-type GaN layer 7 and the P-type GaN layer 6.

Two-dimensional electron gas 28 is generated in the intrinsic GaN layer 8 in the vicinity of the interface between the intrinsic GaN layer 8 and the N-type AlGaN layer 9, due to a piezoelectric effect.

The intrinsic GaN layer 8 is formed on the sapphire substrate 1 by the so-called epitaxial lateral overgrowth (ELO), and has a region exhibiting a high dislocation density and regions (dislocation-free regions) exhibiting small dislocation densities in the horizontal direction along the substrate surface. The position for forming the trench 16 is so selected that the regions (dislocation-free regions) exhibiting small dislocation densities are positioned immediately under the channel regions 21. The intrinsic GaN layer 8 is so grown on the sapphire substrate 1 that the major surface (surface parallel to the sapphire substrate 1) thereof is defined by a C-plane (0001), for example. In this case, it follows that the N-type AlGaN layer 9, the N-type GaN layer 5, the P-type GaN layer 6 and the N-type GaN layer 7 stacked on the intrinsic GaN layer 8 by epitaxy are stacked also with major surfaces defined by C-planes (0001). The wall surfaces of the sectionally-shaped trench 16 are defined by nonpolar planes (m-planes (10-10) or a-planes (11-20)), or semipolar planes ((10-1-1), (10-1-3), (11-22) or the like), for example.

The intrinsic GaN layer 8 may be so grown on the sapphire substrate 1 that the major surface thereof is defined by a nonpolar plane (an m-plane (10-10) or an a-plane (11-20)) or a semipolar plane ((10-1-1), (10-1-3), (11-22) or the like) In this case, it follows that the N-type AlGaN layer 9, the N-type GaN layer 5, the P-type GaN layer 6 and the N-type GaN layer 7 are stacked with major surfaces defined by the corresponding crystal planes, accordingly.

The gate insulating film 19 can be constituted of a nitride or an oxide, for example. More specifically, the quantity of charge on the interface between the gate insulating film 19 and the P-type GaN layer 6 can be reduced and carrier mobility in the channel regions 21 can be improved when constituting the gate insulating film of silicon nitride (SiₓN_{y}) or silicon oxide. In other words, channel resistance can be reduced.

The gate electrode 20 is constituted of a conductive material such as an Ni—Ti alloy, an Ni—Ti—Au alloy, a Pd—Au alloy, a Pd—Ti—Au alloy, a Pd—Pt—Au alloy, Pt, Al or polysilicon.

The drain electrodes 15 are preferably constituted of a metal containing at least Al, and can be constituted of a Ti—Al alloy, for example. Similarly, the source electrodes 25 are also preferably constituted of a metal containing Al, and can be constituted of a Ti—Al alloy, for example. The drain electrodes 15 and the source electrodes 25 are so constituted of the metal containing Al that excellent contact with a wiring layer (not shown) can be attained. Alternatively, the drain electrodes 15 and the source electrodes 25 may be constituted of Mo or an Mo compound (molybdenum silicide, for example), Ti or a Ti compound (titanium silicide, for example), or W or a W compound (tungsten silicide, for example).

The operation of the aforementioned MIS field-effect transistor is now described.

A bias voltage positive on the side of the drain electrodes 15 is supplied between the source electrodes 25 and the drain electrodes 15. Thus, a reverse voltage is supplied to the P-N junction on the interface between the N-type GaN layer 5 and the P-type GaN layer 6, and the N-type GaN layers 5 and 7, i.e., the source and the drain are cut off as a result. When a prescribed voltage positive on the side of the gate electrode 20 is supplied between the source electrodes 25 and the gate electrode 20 in this state, a bias with respect to the P-type GaN layer 6 is supplied to the gate electrode 20. Thus, electrons are induced in the channel regions 21 of the P-type GaN layer 6, and inversion channels are formed. The N-type GaN layers 5 and 7 conduct through these inversion channels. Thus, it follows that the source and the drain conduct. In other words, the source and the drain conduct when a prescribed bias is supplied to the gate electrode 20, while the source and the drain are cut off when no bias is supplied to the gate electrode 20. Thus, the normally-off operation is enabled.

When the inversion channels are formed in the channel regions 21, electrons supplied from the source electrodes 25 flow into the N-type GaN layer 5 from the N-type GaN layer 7 through the channel regions 21, and head toward the drain electrodes 15 via the two-dimensional electron gas 28. The two-dimensional electron gas 28 is widely distributed on the interface between the intrinsic GaN layer 8 and the N-type AlGaN layer 9, whereby the electrons flowing into the N-type GaN layer 5 from the channel regions 21 flow into the two-dimensional electron gas 28 through a wide range of the N-type GaN layer 5. Thus, concentration of a current can be relaxed and the on-resistance can be suppressed, despite the structure of extracting the drain electrodes 15 in the lateral direction of the nitride semiconductor multilayer structure portion 2.

FIGS. 2A to 2E are schematic sectional views showing a method for manufacturing the MIS field-effect transistor of FIG. 1 in step order.

First, the intrinsic GaN layer 8 is formed on the sapphire substrate 1 by epitaxial lateral overgrowth (refer to Patent Document 2). Then, the N-type AlGaN layer 9, the N-type GaN layer 5, the P-type GaN layer 6 and the N-type GaN layer 7 are successively grown on this intrinsic GaN layer 8 by epitaxy. Thus, the nitride semiconductor multilayer structure portion 2 is formed on the sapphire substrate 1 (see FIG. 2A).

Regarding the substance obtained by forming the intrinsic GaN layer 8 on the sapphire substrate 1 by epitaxial lateral overgrowth as the “substrate”, it may be conceived that the “nitride semiconductor multilayer structure portion” is constituted of the group III-V nitride semiconductor layers stacked above this intrinsic GaN layer 8. Alternatively, a substance obtained by previously forming a GaN layer on a sapphire substrate (bare substrate) by epitaxial lateral overgrowth may be employed as the sapphire substrate 1, for forming the intrinsic GaN layer 8 on this sapphire substrate 1 by ordinary epitaxy. Also in this case, the intrinsic GaN layer 8 inherits dislocations from the underlayer thereof, to have the region exhibiting a high dislocation density and the regions (dislocation-free regions) exhibiting low dislocation densities.

When forming the intrinsic GaN layer 8, the intrinsic GaN layer 8 may be intentionally doped with no impurity, or the epitaxy may be performed while doping the intrinsic GaN layer 8 with Mg, C or Fe as a P-type dopant. The GaN layer is somewhat N-typed when epitaxially grown with no addition of a P-type dopant, and hence the P-type dopant is introduced in order to correct this. Mg, C or Fe may be employed also as a P-type dopant added when epitaxially growing the P-type GaN layer 6.

Si, for example, may be employed as an N-type dopant when epitaxially growing the N-type AlGaN layer 9 and the N-type GaN layers 5 and 7.

After the nitride semiconductor multilayer structure portion 2 is formed, the nitride semiconductor multilayer structure portion 2 is etched in a striped manner, as shown in FIG. 2B. In other words, sectionally rectangular grooves 30 reaching a layer-thickness intermediate portion of the N-type AlGaN layer 9 from the N-type GaN layer 7 through the P-type GaN layer 6 and the N-type GaN layer 5 are formed by etching. Thus, a plurality of nitride semiconductor multilayer structure portions 2 are shaped in a striped manner on the sapphire substrate 1, while the drawn portions 10 consisting of the extensions of the N-type GaN layer 9 are formed at the same time. Then, a pair of source electrode trenches 24 are formed along both side edges of each shaped nitride semiconductor multilayer structure portion 2 respectively.

These source electrode trenches 24 are sectionally rectangular groove portions reaching the P-type GaN layer 6 from the N-type GaN layer 7, as hereinabove described.

The source electrode trenches 24 can be formed by dry etching (anisotropic etching) employing plasma, for example. Further, a wet etching treatment for improving trench inner wall surfaces damaged by the dry etching may be thereafter performed, if necessary. Thus, contact resistance of the source electrodes 25 can be reduced. An alkaline solution such as KOH (potassium hydroxide) or NH₄OH (ammonia water) is preferably employed for the wet etching.

After the source electrode trenches 24 are formed in this manner, the drain electrodes 15 and the source electrodes 25 are formed respectively, thereby providing the state of FIG. 2B. The drain electrodes 15 are formed to be in contact with the bottom surfaces of the grooves 30, i.e., the surfaces of the drawn portions 10 (extensions of the N-type AlGaN layer 9).

Then, the sectionally V-shaped trench 16 is formed in the vicinity of the width-directional intermediate portion of each nitride semiconductor multilayer structure portion 2 along the longitudinal direction of the nitride semiconductor multilayer structure portion 2, as shown in FIG. 2C. The position for forming the trench 16 is so set that the dislocation-free regions of the P-type GaN layer 6 are exposed from the sidewalls thereof to form the wall surfaces 17. This formation of the trench 16 includes a step of forming the V-shaped trench 16 reaching the N-type GaN layer 5 from the N-type GaN layer 7 through the P-type GaN layer 6 by dry etching (anisotropic etching) employing plasma and a wet etching step for improving the exposed surfaces damaged by the dry etching. In other words, the wet etching treatment is performed on the wall surfaces 17 damaged by the dry etching, whereby it follows that there appear new wall surfaces 17 from which damaged surface layers have been removed.

An alkaline solution such as KOH (potassium hydroxide) or NH₄OH (ammonia water) is preferably employed for the wet etching. Thus, less damaged wall surfaces 17 can be obtained. The damages of the wall surfaces 17 are so reduced that the crystal states of the channel regions 21 can be excellently kept and the interfaces between the wall surfaces 17 and the gate insulating film 19 can be rendered excellent, whereby the interfacial levels can be reduced. Thus, the channel resistance can be reduced, and a leakage current can be suppressed.

Then, the gate insulating film 19 covering the wall surfaces 17 of the V-shaped trench 16 and covering the edge portions of the trench 16 are formed, as shown in FIG. 2D. ECR (Electron Cyclotron Resonance) sputtering is preferably applied to the formation of the gate insulating film 19.

Thereafter the gate electrodes 20 are formed as shown in FIG. 2E, whereby the MIS field-effect transistor of the structure shown in FIG. 1 can be obtained.

The plurality of nitride semiconductor multilayer structure portions 2 formed on the sapphire substrate 1 in stripes form unit cells respectively. The drain electrodes 15, the gate electrodes 20 and the source electrodes 25 of the plurality of nitride semiconductor multilayer structure portions 2 are connected in common on unshown positions respectively. The drain electrodes 15 can be shared between adjacent nitride semiconductor multilayer structure portions 2.

According to this embodiment, as hereinabove described, the vertical transistor structure obtained by stacking the N-type GaN layer 5, the P-type GaN layer 6 and the N-type GaN layer 7 is so employed that a field-effect transistor capable of a normally-off operation, capable of feeding a high current and having a high breakdown voltage can be implemented. Further, the intrinsic GaN layer 8 and the N-type AlGaN layer 9 are stacked on the sapphire substrate 1 and the drain electrodes 15 are formed in contact with the drawn portions 10 of the N-type AlGaN layer 9, whereby the electrons flowing into the N-type GaN layer 5 flow into the two-dimensional electron gas 28 through the wide range of this N-type GaN layer 5, and move toward the drain electrodes 15 provided on the side portions of the nitride semiconductor multilayer structure portion 2. Thus, concentration of a high current can be relaxed while employing the structure of laterally extracting the drain electrodes 15, and hence the on-resistance can be effectively reduced. Moreover, a vertical field-effect transistor can be constituted and concentration of the current can be relaxed while employing the insulating sapphire substrate 1.

FIG. 3 is a schematic sectional view for illustrating the structure of an MIS field-effect transistor according to a second embodiment of the present invention. Referring to FIG. 3, reference numerals identical to those in the case of FIG. 1 are allocated to portions corresponding to the portions in the above FIG. 1.

According to this embodiment, a conductive substrate 41 is employed. A nitride semiconductor multilayer structure portion 2 is formed on one surface of this conductive substrate 41. According to this embodiment, the nitride semiconductor multilayer structure portion 2 is constituted of an N-type GaN layer 5 formed on the surface of the conductive substrate 41, a P-type GaN layer 6 stacked thereon, and an N-type GaN layer 7 stacked thereon. A drain electrode 15 is formed in contact with the other surface of the conductive substrate 41. In this embodiment, therefore, it follows that the drain electrode 15 is electrically connected to the N-type GaN layer 5 through the conductive substrate 41. The remaining structure is similar to that in the case of the aforementioned first embodiment, and the operation is also similar.

The conductive substrate 41 is in contact with the N-type GaN layer 5 along the overall region of the surface thereof, whereby electrons fed to the N-type GaN layer 5 through channel regions 21 head toward the conductive substrate 41 through a wide range of this N-type GaN layer 5, and flow into the drain electrode 15 through this conductive substrate 41. Thus, current concentration can be suppressed.

A ZnO substrate, an Si substrate, a GaAs substrate, a GaN substrate or an SiC substrate can be applied as the conductive substrate 41. In particular, the GaN substrate is most preferably employed. The GaN substrate is so employed as the conductive substrate 41 that the lattice constants of the same and the N-type GaN layer 5 formed on the surface thereof can be matched with each other. Therefore, the nitride semiconductor multilayer structure portion 2 having a small number of lattice defects can be obtained by employing the GaN substrate as the conductive substrate 41 and successively epitaxially growing the N-type GaN layer 5, the P-type GaN layer 6 and the N-type GaN layer 7 on the surface of this conductive substrate 41.

When employing the conductive substrate 41 whose major surface is defined by a C-plane (0001), it follows that the N-type GaN layer 5, the P-type GaN layer 6 and the N-type GaN layer 7 stacked on the conductive substrate 41 by epitaxy are stacked also with major surfaces defined by C-planes (0001). Wall surfaces 17 of a sectionally V-shaped trench 16 are defined by nonpolar planes (m-planes (10-10) or a-planes (11-20)) or semipolar planes ((10-1-1), (10-1-3), (11-22) or the like), for example.

A substrate whose major surface is defined by a nonpolar plane (an m-plane (10-10) or an a-plane (11-20)) or a semipolar plane ((10-1-1), (10-1-3), (11-22) or the like) may be employed as the conductive substrate 41. In this case, it follows that the N-type GaN layer 5, the P-type GaN layer 6 and the N-type GaN layer 7 are stacked with major surfaces defined by the corresponding crystal planes, accordingly.

FIGS. 4A to 4E are schematic sectional views showing a method for manufacturing the field-effect transistor of FIG. 3 in step order. The N-type GaN layer 5, the P-type GaN layer 6 and the N-type GaN layer 7 are successively epitaxially grown on the conductive substrate 41, whereby the nitride semiconductor multilayer structure portion 2 is formed (see FIG. 4A).

Then, sectionally rectangular source electrode trenches 24 are formed in a striped manner with respect to the nitride semiconductor multilayer structure portion 2, and source electrodes 25 are embedded in the source electrode trenches 42 (FIG. 4B). The field-effect transistor according to this embodiment has a structure of extracting the drain electrode 15 from the lower surface side (opposite to the nitride semiconductor multilayer structure portion 2) of the conductive substrate 41, whereby the nitride semiconductor multilayer structure portion 2 may not be divided into a plurality of portions, but can be employed in a state integrated on the conductive substrate 41.

Then, the sectionally V-shaped trench 16 is formed around an intermediate portion between each adjacent pair of source electrode trenches 24 by dry etching similarly to the case of the first embodiment, and damaged layers of the wall surfaces 17 are further removed by wet etching (see FIG. 4C) After a gate insulating film 19 covering the wall surfaces 17 of the trench 16 is formed as shown in FIG. 4D, the drain electrode 15 and a gate electrode 20 are formed, as shown in FIG. 4E. The drain electrode 15 is formed to be in contact with the lower surface of the conductive substrate 41 in this case.

Thus, a field-effect transistor having a plurality of cells can be prepared with unit cells formed by the portions of the individual trenches 16. Each adjacent pair of cells share a source electrode 25 arranged therebetween. The gate electrodes 20 and the source electrodes 25 of the plurality of cells are connected in common on unshown positions respectively, similarly to the case of the aforementioned first embodiment. The drain electrode 15, formed in contact with the conductive substrate 41, is an electrode common to all cells.

FIG. 5 is a schematic sectional view for illustrating the structure of an MIS field-effect transistor according to a third embodiment of the present invention. Referring to FIG. 5, the same reference numerals are allocated to portions corresponding to the respective portions shown in the above FIG. 3. According to this embodiment, no substrate is provided, while a drain electrode 15 is formed in contact with a surface opposite to a gate electrode 20 in a nitride semiconductor multilayer structure portion 2. More specifically, the drain electrode 15 is applied/formed to generally cover the overall region of the lower surface (surface opposite to the gate electrode 20) of an N-type GaN layer 5. Therefore, this field-effect transistor can be formed in an extremely small thickness, and the thickness of the overall device reaching the upper surface(s) of the gate electrode 20 or source electrodes 25 from the drain electrode 15 can be set to not more than 30 μm. Further, electrons flowing into the N-type GaN layer 5 diffuses and flows in a wide range of this N-type GaN layer 5, to flow into the drain electrode 15. Therefore, concentration of a current can be suppressed.

FIGS. 6A to 6F are schematic sectional views showing a method for manufacturing the field-effect transistor of FIG. 5 in step order. The N-type GaN layer 5, a P-type GaN layer 6 and an N-type GaN layer 7 are successively epitaxially grown on a substrate 45, whereby the nitride semiconductor multilayer structure portion 2 is formed (see FIG. 6A).

A sapphire substrate, a ZnO substrate, an Si substrate, a GaAs substrate, a GaN substrate or an SiC substrate can be applied as the substrate 45. Employment of the GaN substrate is most preferable in view of the matching property of the lattice constant with the nitride semiconductor layers. However, a GaN epitaxial growth layer may be formed on a sapphire substrate, for example, by epitaxial lateral overgrowth so that this is employed as the substrate 45 and the N-type GaN layer 5, the P-type GaN layer 6 and the N-type GaN layer 7 are successively epitaxially grown on the GaN epitaxial growth layer.

When employing the substrate 45 whose major surface is defined by a C-plane (0001), it follows that the N-type GaN layer 5, the P-type GaN layer 6 and the N-type GaN layer 7 stacked on this substrate 45 by epitaxy are stacked with major surfaces defined by C-planes (0001). Further, wall surfaces 17 of a sectionally V-shaped trench 16 formed later are defined by nonpolar planes (m-planes (10-10) or a-planes (11-20)) or semipolar planes ((10-1-1), (10-1-3), (11-22) or the like), for example. A substrate whose major surface is defined by a nonpolar plane (an m-plane (10-10) or an a-plane (11-20)) or a semipolar plane ((10-1-1), (10-1-3), (11-22) or the like) may be employed as the substrate 45. In this case, it follows that the N-type GaN layer 5, the P-type GaN layer 6 and the N-type GaN layer 7 are stacked with major surfaces defined by the corresponding crystal planes, accordingly.

Then, sectionally rectangular source electrode trenches 24 are formed in a striped manner with respect to the nitride semiconductor structure portion 2, and the source electrodes 25 are embedded in these source electrode trenches 24 (FIG. 6B). The field-effect transistor according to this embodiment has a structure of extracting the drain electrode 15 from the lower surface side (opposite to the gate electrode 20) of the nitride semiconductor multilayer structure portion 2, whereby the nitride semiconductor multilayer structure portion 2 may not be divided into a plurality of portions.

Then, the sectionally V-shaped trench 16 is formed around an intermediate portion between each adjacent pair of source electrode trenches 24 by dry etching similarly to the case of the first embodiment, and damaged layers of the wall surfaces 17 are further removed by wet etching (see FIG. 6C) In addition, a gate insulating film 19 covering the wall surfaces 17 of the trench 16 is formed as shown in FIG. 6D, and the gate electrode 20 is formed to cover this.

Then, the substrate 45 is removed, as shown in FIG. 6E. The removal of the substrate 45 can be performed by a laser lift-off method of applying a laser beam from the surface of the substrate 45 and separating the substrate 45. Alternatively, the same can be performed also by a CMP (chemical mechanical polishing) treatment or an etching treatment.

Thereafter the drain electrode 15 is formed, as shown in FIG. 6F. The drain electrode 15 is formed in contact with the N-type GaN layer 5 in this case.

Thus, a field-effect transistor having a plurality of cells can be prepared with unit cells formed by the portions of the individual trenches 16. Each adjacent pair of cells share the source electrode 25 arranged therebetween, similarly to the case of the aforementioned second embodiment. The gate electrodes 20 and the source electrodes 25 of the plurality of cells are connected in common on unshown positions respectively. The drain electrode 15, formed in contact with the N-type GaN layer 5, is an electrode common to all cells.

FIG. 7 is a schematic sectional view for illustrating the structure of an MIS field-effect transistor according to a fourth embodiment of the present invention. Referring to FIG. 7, reference numerals identical to those in the case of FIG. 3 are allocated to portions corresponding to the respective portions shown in the above FIG. 3. According to this embodiment, a gate insulating film 50 is formed by an AlGaN regrowth layer 51 regrown (epitaxially grown) from wall surfaces 17 of a trench 16 and an insulating film 52 stacked and formed on the surface of the AlGaN regrowth layer 51. The gate insulating film 50 is formed over a region covering the wall surfaces 17 of the trench 16 and reaching edge portions of the trench 16 on the upper surface of an N-type GaN layer 7, similarly to the gate insulating film 19 in the aforementioned embodiment.

The AlGaN regrowth layer 51 is epitaxially grown from the wall surfaces 17 which are GaN crystal surfaces after forming the trench 16 by dry etching and shaping the wall surfaces 17 by a wet etching treatment. The aluminum composition of this AlGaN regrowth layer 51 is set to not less than 50% and less than 10%. The AlGaN regrowth layer 51 preferably contains no In. Further, the wall surfaces 17 on which the AlGaN regrowth layer 51 is formed are preferably defined by nonpolar planes (m-planes (10-10) or a-planes (11-20)), or semipolar planes ((10-1-1), (10-1-3), (11-22) or the like).

The insulating film 52 stacked on the AlGaN regrowth layer 51 can be prepared from a nitride or an oxide, for example. The insulating film 52 improves the insulating property of the gate insulating film 50 as a whole, thereby contributing to suppression of a gate leakage current. If the insulating property of the AlGaN regrowth layer 51 is sufficient, the insulating film 52 may be omitted.

According to the structure of this embodiment, the interfaces between the gate insulating film 50 and the wall surfaces 17 are bonded surfaces between GaN crystals and an AlGaN crystal, and hence the same are stable interfaces, whereby the quantity of interfacial charge can be reduced. Thus, mobility in channel regions 21 can be improved and a leakage current can be suppressed, whereby the reliability of the device can be improved as a result.

FIGS. 8A to 8F are schematic sectional views showing a method for manufacturing the field-effect transistor of FIG. 7 in step order. An N-type GaN layer 5, a P-type GaN layer 6 and the N-type GaN layer 7 are successively epitaxially grown on a conductive substrate 41, whereby a nitride semiconductor multilayer structure portion 2 is formed (see FIG. 8A).

Then, sectionally V-shaped trenches 16 are formed in a striped manner by dry etching with respect to the nitride semiconductor multilayer structure portion 2, and damaged layers of the wall surfaces 17 are further removed by wet etching (see FIG. 8B). Then, the AlGaN regrowth layer 51 is formed by epitaxy from the wall surfaces 17 of each trench 16, as shown in FIG. 8C. This AlGaN regrowth layer 51 is an intrinsic semiconductor layer, and grown to a layer thickness of about 1000 Å, for example.

Thereafter sectionally rectangular source electrode trenches 24 are formed around intermediate portions between adjacent V-shaped trenches 16 in a striped manner, and source electrodes 25 are formed to embed these, as shown in FIG. 8D.

Thereafter the insulating film 52 is stacked on the AlGaN regrowth layer 51, as shown in FIG. 8E. After the gate insulating film 50 is formed in this manner, a gate electrode 20 is formed. Thereafter a drain electrode 15 is formed, as shown in FIG. 8F. The drain electrode 15 is formed to be in contact with the lower surface of the conductive substrate 41.

Thus, a field-effect transistor having a plurality of cells can be prepared with unit cells formed by the portions of the individual trenches 16. The gate electrodes 20 and the source electrodes 25 of the plurality of cells are connected in common on unshown positions respectively. The drain electrode 15, formed in contact with the conductive substrate 41, is an electrode common to all cells.

FIG. 9 is a schematic sectional view for illustrating the structure of an MIS field-effect transistor according to a fifth embodiment of the present invention. Referring to FIG. 9, reference numerals identical to those in the case of FIG. 3 are allocated to portions corresponding to the respective portions shown in the above FIG. 3. According to this embodiment, an N-type AlGaN layer 55 is applied in place of the N-type GaN layer 5 in the aforementioned embodiment, and an N-type AlGaN layer 57 is further employed in place of the N-type GaN layer 7. In other words, the N-type AlGaN layer 55 is formed on the surface of a conductive substrate 41 by epitaxy, a P-type GaN layer 6 is further formed on the N-type AlGaN layer 55 similarly by epitaxy, and the N-type AlGaN layer 57 is formed on the surface of the P-type GaN layer 6 also by epitaxy.

A trench 16 is formed in a depth reaching the N-type AlGaN layer 55 from the N-type AlGaN layer 57 through the P-type GaN layer 6, and formed in a sectionally V-shaped manner in this embodiment. A gate insulating film 19 and a gate electrode 20 are stacked/formed on wall surfaces 17 of this trench 16, similarly to the case of the aforementioned third embodiment.

Source electrode trenches 24 reaching the P-type GaN layer 6 from the N-type AlGaN layer 57 are formed on positions different from the trench 16. Source electrodes 25 are embedded in these source electrode trenches 24. Therefore, the source electrodes 25 are in contact with the N-type AlGaN layer 57 forming a source layer and also in contact with the P-type GaN layer 6, to fix the potential of the P-type GaN layer 6 equally to the potential of the N-type AlGaN layer 57 as the source layer.

Thus, a double heterostructure sandwiching the P-type GaN layer 6 with the N-type AlGaN layers 55 and 57 is formed. The band gaps of the AlGaN layers 55 and 57 are wider than the band gap of the GaN layer 6, whereby only the band gap of the P-type GaN layer 6 constituting channel regions 21 is small. Thus, the breakdown voltage of the device can be further improved.

This field-effect transistor can be prepared by a method similar to the method described with reference to FIGS. 4A to 4E. In other words, the N-type AlGaN layer 55 may be epitaxially grown on the surface of the conductive substrate 41 in place of the N-type GaN layer 5, and the N-type AlGaN layer 57 may be epitaxially grown on the P-type GaN layer 6 in place of the N-type GaN layer 7.

When employing the conductive substrate 41 whose major surface is defined by a C-plane (0001), it follows that the N-type AlGaN layer 55, the P-type GaN layer 6 and the N-type AlGaN layer 57 stacked on this conductive substrate 41 by epitaxy are stacked also with major surfaces defined by C-planes (0001). Further, the wall surfaces 17 of the sectionally V-shaped trench 16 are defined by nonpolar planes (m-planes (10-10) or a-planes (11-20)) or semipolar planes ((10-1-1), (10-1-3), (11-22) or the like), for example.

A substrate whose major surface is defined by a nonpolar plane (an m-plane (10-10) or an a-plane (11-20)) or a semipolar plane ((10-1-1), (10-1-3), (11-22) or the like) may be employed as the conductive substrate 41. In this case, it follows that the N-type AlGaN layer 55, the P-type GaN layer 6 and the N-type AlGaN layer 57 are stacked with major surfaces defined by the corresponding crystal planes, accordingly.

FIG. 10 is a schematic sectional view for illustrating the structure of an MIS field-effect transistor according to a sixth embodiment of the present invention. Referring to FIG. 10, the same reference numerals are allocated to portions corresponding to the respective portions shown in the above FIG. 1.

According to this embodiment, a gate insulating film 19 consists of a combination of silicon nitride and silicon oxide. More specifically, the gate insulating film 19 is constituted of a silicon nitride film 191, covering the overall surface of a nitride semiconductor multilayer structure portion 2, formed on the surface of the nitride semiconductor multilayer structure portion 2, and a silicon oxide film 192 formed on this silicon nitride film 191. In other words, the silicon nitride film 191 is formed in contact with wall surfaces 17 in a trench 16.

The thickness of the silicon nitride film 191 is preferably 1 Å to 100 Å, for example, and more preferably around 10 Å. On the other hand, the thickness of the silicon oxide film 192 is preferably 100 Å to 3000 Å, for example, and more preferably 1000 Å to 2000 Å.

The gate insulating film 19 is etched up to such a depth that an N-type GaN layer 7 and drawn portions 10 are exposed in the drawn portions 10 in the N-type GaN layer 7 and an N-type AlGaN layer 9. Source electrodes 25 are formed on the upper surfaces of the exposed portions of this N-type GaN layer 7. Further, drain electrodes 15 are formed on the upper surfaces of the exposed drawn portions 10. The remaining structure is similar to that in the case of the aforementioned first embodiment, and the operation is also similar. The insulating film in contact with the wall surfaces 17 is the silicon nitride film 191, whereby interfacial charge on the wall surfaces 17 can be suppressed, and an off-leakage current can be reduced. Consequently, a transistor operation can be improved. Silicon oxynitride (SiON) may be employed, if necessary. The silicon oxynitride may be formed by mixing oxygen into silicon nitride, or may be formed by mixing nitrogen into silicon oxide.

FIGS. 11A to 11F are schematic sectional views showing a method for manufacturing the field-effect transistor of FIG. 10 in step order.

First, an intrinsic GaN layer 8 is formed on a sapphire substrate 1. Then, the N-type AlGaN layer 9, an N-type GaN layer 5, a P-type GaN layer 6 and an N-type GaN layer 7 are successively grown on this intrinsic GaN layer 8 by epitaxy. Thus, the nitride semiconductor multilayer structure portion 2 is formed on the sapphire substrate 1 (see FIG. 11A).

After the nitride semiconductor multilayer structure portion 2 is formed, the nitride semiconductor multilayer structure portion 2 is etched in a striped manner, as shown in FIG. 11B. In other words, sectionally rectangular grooves 31 reaching a layer-thickness intermediate portion of the N-type AlGaN layer 9 are formed by etching from the N-type GaN layer 7 through the P-type GaN layer 6 and the N-type GaN layer 5. Then, a photoresist film (not shown) having openings in regions for forming a drain electrode 15 and the source electrodes 25 is formed by well-known photolithography, and a metal (platinum, aluminum or the like, for example) employed as the material for these electrodes (15 and 25) is formed by sputtering or the like. Thereafter the photoresist film is so removed that unnecessary portions (portions other than the electrodes (15 and 25)) of the metal are lifted off along with the photoresist film. Thus, the drain electrodes 15 and the source electrodes 25 are formed to be in contact with the upper surfaces of the drawn portions 10 and the upper surface portions of the N-type GaN layer 7 respectively (see FIG. 11C). After the drain electrodes 15 and the source electrodes 25 are formed, thermal alloying (annealing treatment) is performed.

Then, the sectionally V-shaped trench 16 is formed around a width-directional central portion of each nitride semiconductor multilayer structure portion 2 along the longitudinal direction of the nitride semiconductor multilayer structure portion 2 (see FIG. 11D). The position for forming the trench 16 is so set that dislocation-free regions of the P-type GaN layer 6 are exposed from the sidewalls thereof to form the wall surfaces 17. Then, the gate insulating film 19 is formed on the nitride semiconductor multilayer structure portion 2 by ECR (electron cyclotron resonance) sputtering, for example, as shown in FIG. 11E. In order to form the gate insulating film 19 by ECR sputtering, a substrate 1 on which the nitride semiconductor multilayer structure portion 2 is formed is first introduced into an ECR film forming apparatus, and the silicon nitride film 191 covering the overall surface of the nitride semiconductor multilayer structure portion 2 is formed. At this time, the film forming quantity of silicon nitride is so controlled that the silicon nitride film 191 has the aforementioned thickness. After the silicon nitride film 191 is formed, the silicon oxide film 192 covering the overall surface of the silicon nitride film 191 is formed. Thus, the gate insulating film 19 consisting of the multilayer structure of the silicon nitride film 191 and the silicon oxide film 192 is formed. Thereafter unnecessary portions (portions of the electrodes (15 and 25)) of the gate insulating film 19 are removed by etching.

Then, the gate electrode 20 opposed to the wall surfaces 171 through the gate insulating film 19 is formed by a method similar to that in the case of the drain electrodes 15 and the source electrodes 25 (see FIG. 11F).

Thus, a field-effect transistor having a plurality of cells can be prepared with unit cells formed by portions of the individual trenches 16. Each adjacent pair of cells share a source electrode 25 arranged therebetween. The drain electrodes 15, the gate electrodes 20 and the source electrodes 25 of the plurality of cells are connected in common on unshown positions respectively, similarly to the case of the aforementioned first embodiment. Each drain electrode 15 can be shared between each adjacent pair of nitride semiconductor multilayer structure portions 2.

FIG. 12 is a schematic sectional view for illustrating the structure of an MIS field-effect transistor according to a seventh embodiment of the present invention. Referring to FIG. 12, the same reference numerals are allocated to portions corresponding to the respective portions shown in the above FIG. 1.

According to this embodiment, no N-type AlGaN layer 9 is included, while an N-type GaN layer 5 includes a lower N-type GaN layer 501 (lower layer) stacked on an intrinsic GaN layer 8 and an upper N-type GaN layer 502 (upper layer) stacked on this N-type GaN layer 501.

The impurity concentration (concentration of an N-type impurity in this embodiment) in the N-type GaN layer 502 is 10¹⁵ to 10¹⁸ cm⁻³, for example, and the impurity concentration in the N-type GaN layer 501 is 10¹⁷ to 10¹⁹ cm⁻³, for example. In other words, the impurity concentration in the N-type GaN layer 502 is smaller than the impurity concentration in the N-type GaN layer 501. The remaining structure is similar to that in the case of the aforementioned first embodiment, and the operation is also similar. The impurity concentration in the N-type GaN layer 502 is smaller than the impurity concentration in the N-type GaN layer 501, whereby a depletion layer can be spread toward the side of the N-type GaN layer 502 when the transistor operates in a saturation region. Therefore, reach-through break down resulting from the depletion layer spreading toward the side of a P-type GaN layer 6 can be suppressed. Further, the impurity concentration in the N-type GaN layer 501 is larger than the impurity concentration in the N-type GaN layer 502, whereby on-resistance can be reduced.

This field-effect transistor can be prepared by a method similar to the method described with reference to FIGS. 2A to 2E. In other words, the N-type GaN layer 501 and the N-type GaN layer 502 may be epitaxially grown on an intrinsic GaN layer 8 in this order.

FIG. 13 is a schematic sectional view for illustrating the structure of an MIS field-effect transistor according to an eighth embodiment of the present invention. Referring to FIG. 12, the same reference numerals are allocated to portions corresponding to the respective portions shown in the above FIG. 1.

According to this embodiment, an intrinsic GaN layer 511 is applied in place of the intrinsic GaN layer 8. Further, an N-type AlGaN layer 512 is applied onto this intrinsic GaN layer 511, in place of the N-type AlGaN layer 9 and the N-type GaN layer 5. Thus, an N-type nitride semiconductor layer 500 consisting of the intrinsic GaN layer 511 and the N-type AlGaN layer 512 stacked on this intrinsic GaN layer 511 is stacked on a substrate 1. In other words, the N-type nitride semiconductor layer 500 is formed by a plurality of (two in FIG. 13) layers having different compositions.

In place of the N-type GaN layer 7, an N-type nitride semiconductor layer 73 consisting of an N-type GaN layer 71 and an N-type AlGaN layer 72 stacked on this N-type GaN layer 71 is provided on a P-type GaN layer 6. In other words, the N-type nitride semiconductor layer 73 is formed by a plurality of (two in FIG. 13) layers having different compositions.

Drawn portions 10 are formed by extensions of the N-type AlGaN layer 512, and drain electrodes 15 are formed to be in contact with this N-type AlGaN layer 512.

No trenches 24 are formed in an nitride semiconductor multilayer structure portion 2, while source electrodes 25 are formed to be in contact with the upper surface of an N-type AlGaN superlattice layer 72.

Each N-type AlGaN layer (512 or 72) is generally expressed in AlₓGa_{y}N (0≦x≦1, 0≦y≦1 and 0≦x+y≦1), and expressed in Al_{0.2}Ga_{0.8}N, for example.

The remaining structure is similar to that in the case of the aforementioned first embodiment, and the operation is also similar. When each N-type AlGaN layer (512 or 72) has the composition expressed in Al_{0.2}Ga_{0.8}N as hereinabove described, two-dimensional electron gas having a sheet carrier density of 1×10¹³ cm⁻³ and electron mobility of 1000 cm²/V·s is formed around the boundary between each N-type AlGaN layer (512 or 72) and each GaN layer (511 or 71) in contact therewith. Therefore, resistance parasitic on the source layer (N-type nitride semiconductor layer 73) can be reduced by the two-dimensional electron gas, and on-resistance of the transistor can be reduced.

This field-effect transistor can be prepared by a method similar to the method described with reference to FIGS. 2A to 2E. In other words, the intrinsic GaN layer 511 and the N-type AlGaN layer 512 may be epitaxially grown on a substrate 1 in this order. Further, the N-type GaN layer 71 and the N-type AlGaN layer 72 may be epitaxially grown on the P-type GaN layer 6 in this order.

While the eight embodiments of the present invention have been described, the present invention may be embodied in other ways. For example, the structure of the gate insulating film 50 shown in FIG. 7 can be replaced with the gate insulating film 19 according to the first embodiment (FIG. 1), the third embodiment (FIG. 5), the fifth embodiment (FIG. 9), the seventh embodiment (FIG. 12) and the eighth embodiment (FIG. 13). Further, the multilayer structure of the N-type AlGaN layer 55, the P-type GaN layer 6 and the N-type AlGaN layer 57 shown in the fifth embodiment (FIG. 9) can be employed also in the first embodiment (FIG. 1) and the third embodiment (FIG. 5). While the N-type AlGaN layers 55 and 57 are arranged on both sides of the P-type GaN layer 6 in the fifth embodiment (FIG. 9), the breakdown voltage of the device can be improved also by forming only a layer stacked on one side of the P-type GaN layer 6 by an N-type AlGaN layer. In other words, the N-type GaN layer 5 may be applied without employing the N-type AlGaN layer 55, or the N-type GaN layer 7 may be applied without employing the N-type AlGaN layer 57 in the structure of FIG. 9.

Further, while such an example that the sectionally V-shaped trench 16 is formed on the nitride semiconductor multilayer structure portion 2 has been described in the aforementioned embodiments, the shape of the trench 16 may be another shape such as an inverted trapezoidal shape, a U-shape, a rectangular shape or a trapezoidal shape. In addition, the wall surfaces 17 may not be inclined surfaces inclined with respect to the substrate, and may not be planes either. In other words, the wall surfaces 17 may be planes perpendicular to the substrate, or may be curved surfaces.

While it is assumed that each of the N-type GaN layer 5, the P-type GaN layer 6 and the N-type GaN layer 7 is formed as a single layer in the aforementioned embodiments, the same may be a layer formed by stacking not less than two semiconductor layers having different compositions or impurity concentrations, so far as the layer is made of a group III nitride semiconductor.

While the gate insulating film 19 and the gate electrode 20 are stacked and formed on both of the pair of wall surfaces 17 of the trench 16 in the aforementioned embodiment, the multilayer structure of these may be formed only on one wall surface 17. Further, the nitride semiconductor multilayer structure portion 2 may be etched on a position shown by a two-dot chain line 60 in FIG. 3, so that the device is formed by employing only either side of this two-dot chain line 60, for example. In this case, it follows that the wall surfaces 17 extending over the N-type GaN layer 5, the P-type GaN layer 6 and the N-type GaN layer 7 are formed although no sectionally V-shaped trench is formed on the nitride semiconductor multilayer structure portion 2.

While the present invention has been described in detail byway of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Applications Nos. 2006-228028 and 2007-56430 filed in the Japanese Patent Office on Aug. 24, 2006 and Mar. 6, 2007 respectively, the disclosures of which are incorporated herein by reference in its entirety.

1-40. (canceled)

41. An MIS field-effect transistor comprising:
a nitride semiconductor multilayer structure portion including a first group III-V nitride semiconductor layer of a first conductivity type, a second group III-V nitride semiconductor layer of a second conductivity type stacked on the first group III-V nitride semiconductor layer and a third group III-V nitride semiconductor layer of the first conductivity type stacked on the second group III-V nitride semiconductor layer;
a gate insulating film formed on a wall surface formed over the first, second and third group III-V nitride semiconductor layers to extend over the first, second and third group III-V nitride semiconductor layers;
a gate electrode made of a conductive material formed as being opposed to the second group III-V nitride semiconductor layer with this gate insulating film interposed therebetween;
a drain electrode electrically connected to the first group III-V nitride semiconductor layer; and
a source electrode electrically connected to the third group III-V nitride semiconductor layer, wherein
the gate insulating film includes a first insulating layer formed in contact with the wall surface, and a second insulating layer stacked on the first insulating layer.

42. (canceled)

43. The MIS field-effect transistor according to claim 41, wherein
the gate insulating film is an insulating film formed by ECR (electron cyclotron resonance) sputtering.

44. The MIS field-effect transistor according to claim 41, wherein
the gate insulating film is an insulating film continuously formed in a film forming apparatus.

45-51. (canceled)

52. The MIS field-effect transistor according to claim 41, wherein
the first layer is made of nitride, and the second layer is made of oxide.

53. The MIS field-effect transistor according to claim 52, wherein
the nitride is silicon nitride, and the oxide is silicon oxide.
